(19) United States
(12) Patent Application Publication
(10) Pub. No.: US 2021/0256177 A1
(43) Pub. Date: Aug. 19, 2021

(54) System and method for creating a 2D floor plan using 3D pictures

(71) Applicant: Pic2Sketch, Dorado, PR (US)

(72) Inventors: Victor Voss, Dorado, PR (US); Jason Male, West Bradenton, FL (US); Aravind Rangesh, Tamil Nadu (IN)

(73) Assignee: Pic2Sketch, Dorado, PR (US)

(21) Appl. No.: 17/176,232

(22) Filed: Feb. 16, 2021

Related U.S. Application Data
(60) Provisional application No. 62/976,878, filed on Feb. 14, 2020.

(51) Int. Cl. G06F 30/13; G06T 11/60; G06T 7/11

(52) U.S. Cl. CPC G06F 30/13; G06T 11/60; G06T 2207/10028; G06T 2207/20132; G06T 7/11

(57) ABSTRACT

The present invention is directed to a system and method for generating two-dimensional floor plans based on captured 3D images of the inside of a room. By receiving images captured with a 3D camera as input, a software system module may analyze the boundaries and walls in a room in order to calculate the distance between them and created a floor plan that provide accurate measurements. Rooms to be analyzed by the system may be captured using a 3D camera or other sensors that allow for depth information. The present invention may further generate reports that provide measurement information about the subject room.

### RELATED APPLICATIONS

This application claims priority from U.S. Provisional Application 62/976,878, filed on Feb. 14, 2020.

### STATEMENT REGARDING FEDERALLY SPONSORED RESEARCH AND DEVELOPMENT

N/A

### BACKGROUND OF THE INVENTION

### Field of the Invention

The present invention is generally directed to a software system for creating two-dimensional floor plans. More particularly, the system is directed at creating 2D floor plans of a building by analyzing 3D pictures of said building. The invention receives 2D/3D pictures or any other data representing a real-world 3D interior as input and, using boundaries specified by a user, generates a 2D floor plan. The inputs may include but not limited to 360-degree images, LIDAR data, SONAR and any other sensor with depth information in future applications.

### Discussion of the Background

A floor plan is a technical drawing that shows the layout of the interior of a building in a two-dimensional manner. Floor plans are a necessary tool for many professionals when building, decorating, furnishing, modifying or designing buildings. Generation of a floor plan usually requires manually measuring the dimensions of the building to be plotted and making sure the drawing includes as much accurate information as possible so the person using the plan may properly interpret it. Presently, calculations for measured drawings are achieved using limited tools, such as measuring tape and laser measure, and other non-standard methods of measurement. These types of tools require physical effort and offer a less than ideal accuracy level. Furthermore, the process of sketching with a pencil and sketchpad and then transferring the drawings to a digital form requires manual work, which results in inconsistent drawings and measurement errors. These methods fail to provide a holistic view of multiple structures of the same building and linking of multiples structures such as windows or walls, requiring massive aggregation efforts. Other sophisticated technologies may address the described issues but are mostly inaccessible due to costs.

The existing art currently provides some solutions for developing 2D floor plans. For example, U. S. Pat. No. 8,705,893 provides a system and method for creating 2D floor plans using a 3D camera by capturing a plurality of images of a space and performing a matching process to align images with one another, determining a subset of points from the image data associated with each image, determining the polylines based on the subset of points, and defining the polygons based on the determined polylines and a determined pose of the camera. This publication, however, does not employ the user of a 3D camera, which may lead to inaccurate boundary markings and distances in the resulting floor plan.

Furthermore, U.S. Patent Application No. 2018/0315162 discloses an invention for generating floor plans by capturing a 3D scan of a building and generating voxels in a three-dimensional grid based on said scan. The voxels are then projected vertically to 2D tiles in a floor plan, resulting in a 2D floor plan of the scanned building. This invention, however, requires 3D scanning, which may raise costs, and uses the volume of the voxels to determine distances, which may result in inaccuracies due to irrelevant objects in the 3D scan.

Therefore, there is a need for a reliable and simple to use system that generates accurate measurements and provides a holistic 2D view of a building interior that reduces digital conversion and manual efforts.

### SUMMARY OF THE INVENTION

All references, including any patents or patent applications cited in this specification are hereby incorporated by reference. No admission is made that any reference constitutes prior art. The discussion of the references states what their authors assert, and the applicants reserve the right to challenge the accuracy and pertinence of the cited documents. It will be clearly understood that, although a number of prior art publications are referred to herein, this reference does not constitute an admission that any of these documents form part of the common general knowledge in the art.

It is acknowledged that the term ‘comprise’ may, under varying jurisdictions, be attributed with either an exclusive or an inclusive meaning. For the purpose of this specification, and unless otherwise noted, the term ‘comprise’ shall have an inclusive meaning—i.e. that it will be taken to mean an inclusion of not only the listed components it directly references, but also other non-specified components or elements. This rationale will also be used when the term ‘comprised’ or ‘comprising’ is used in relation to one or more steps in a method or process.

When the word “invention” is used in this specification, the word “invention” includes “inventions”, that is, the plural of “invention”. By stating “invention”, the Applicant does not in any way admit that the present application does not include more the one patentable and non-obviously distinct invention and Applicant maintains that the present application may include more than one patentably and non-obviously distinct invention. The Applicant hereby asserts, that the disclosure of the present application may include more than one invention, and, if there is more than one invention, that these inventions may be patentable and non-obvious one with respect to the other.

Further, the purpose of the accompanying abstract is to enable the U.S. Patent and Trademark Office and the public generally, and especially the scientists, engineers, and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

The following application discloses a method and system, such as a software platform or web-based tool, for generating 2D floor plans by analyzing 3D pictures. It provides a solution for the current problem of having to manually calculate distances and transferring them to a digital drawing, which oftentimes results in inaccuracies and unreliable plans.

In some embodiments, the software platform is part of a hardware system that includes a camera in order to take pictures of the building for which the floor plans are being made.

In other embodiments, the software platform is a standalone application that may be run on commercially available operating systems and may receive inputs from external sources, captured with different compatibles cameras.

In other embodiments, the present invention may comprise or be compatible with a touchscreen so the user may more intuitively mark boundaries on the 3D pictures that are to be converted in to a 2D floor plan. In other embodiments, this may be done using traditional input method such as a mouse and keyboard.

Other embodiments of the present invention may comprise a reporting module, which allows for delivering information retrieved from uploaded pictures and the generated floor plans.

Further embodiments of the present invention include a report software module which produces a report detailing all the measurements related to the floor, walls and ceiling of the room that was captured in 3D pictures.

### BRIEF DESCRIPTION OF THE DRAWINGS

The accompanying drawings, which are incorporated herein, constitute part of the specifications and illustrate the preferred embodiment of the invention.

FIG. 1 shows a block diagram of the components of the present invention.

FIG. 2 shows a 360-degree image captured by a 3D camera which may be uploaded to the software object of the present invention.

FIG. 3 shows a sphere on which a 3D image maybe “unwrapped” in order to be processed by the present invention. The sphere used here is for reference only. The geometry may evolve in future applications and is not limited to a sphere.

FIG. 4A shows boundary markers specified by a user on a 3D image.

FIG. 4B shows distances on a 2D image calculated from boundary markers created by a user on a 3D image.

FIG. 5 shows how drawn lines from the 3D plane are projected onto a 2D plane surface in order to compute a floor plan.

### DETAILED DESCRIPTION OF THE INVENTION

To provide an overall understanding of the invention, certain illustrative embodiments and examples will now be described. However, it will be understood by one of ordinary skill in the art that the same or equivalent functions and sequences may be accomplished by different embodiments that are also intended to be encompassed within the spirit and scope of the disclosure. The compositions, apparatuses, systems and/or methods described herein may be adapted and modified as is appropriate for the application being addressed and that those described herein may be employed in other suitable applications, and that such other additions and modifications will not depart from the scope hereof.

As used in the specification and claims, the singular forms “a”, “an” and “the” include plural references unless the context clearly dictates otherwise. For example, the term “a transaction” may include a plurality of transaction unless the context clearly dictates otherwise. As used in the specification and claims, singular names or types referenced include variations within the family of said name unless the context clearly dictates otherwise.

The disclosure itself, both as to its configuration and its mode of operation will be best understood, and additional objects and advantages thereof will become apparent, by the following detailed description of a preferred embodiment taken in conjunction with the accompanying drawing.
The Applicant hereby asserts, that the disclosure of the present application may include more than one invention, and, if there is more than one invention, that these inventions may be patentable and non-obvious one with respect to the other.

In the case of a 3D camera with depth information (such as using LIDAR):

A 3D model is first derived from the generated data from the camera sensor, bypassing the need to map it to a 3D geometry such as a sphere. In this case computations are directly made from the 3D model itself, point to point, as if we would measure using a measuring tape. Then, these final measurements along with the angles are used to draw the floor plan, by the computer. Computations are then made from this 3D model instead to calculate room measurements as described in the below paragraphs. In some embodiments, using these measurements, the layout, walls, exits and square footage of the scanned room are determined and a report is produced by a software reporting module for providing users with a convenient way to review the information about the room.

In the case of a regular 360-degree camera capturing 2D photos:

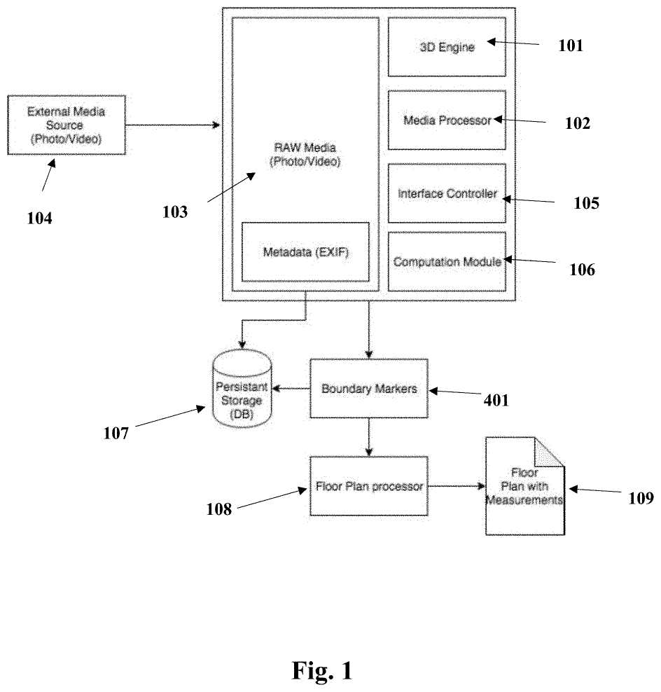

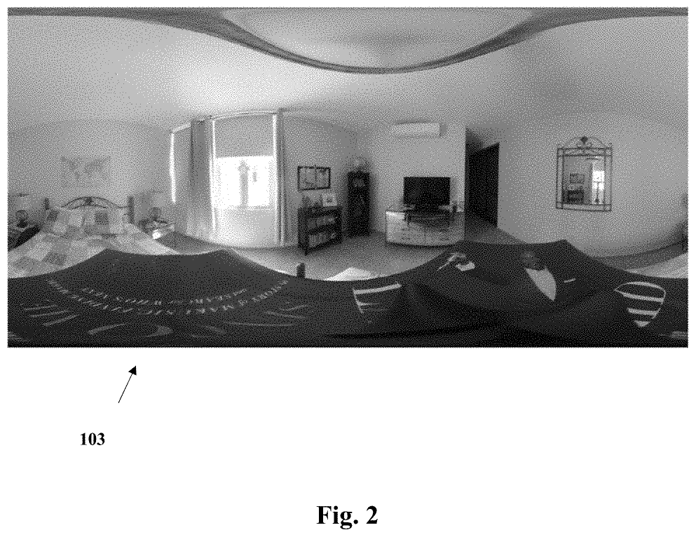

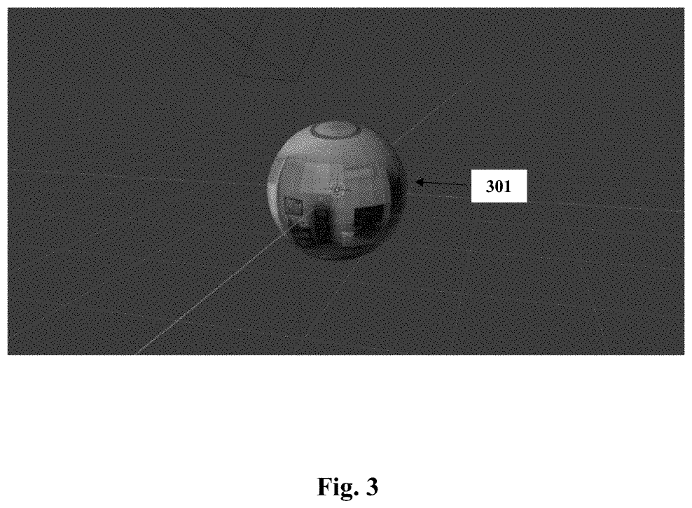

As seen in FIG. 1, the present invention comprises a 3D engine 101 responsible for rendering a 3D sphere (FIG. 3) 301 onto which a 3D image (FIG. 2) 103 captured from a media source 104 is “unwrapped”. Said 3D engine 101 may be a lightweight implementation of a JavaScript-based 3D library compatible with desktop and mobile devices. Other implementations may also be used. The software platform further comprises a media processor 102 responsible for constraining, editing, cropping or changing any other characteristics of the media 103 obtained from the media source 104, such as a 3D camera. The 3D camera or any other media source 104 may provide different types of media 103 to be analyzed by the media processor 102, such as images or video. This media processor 102 serves as the foundation for computer vision applications in further embodiments of the present invention where the floor plan generation maybe completely automated. The platform further comprises an interface controller 105 responsible for generating, updating and keeping the interface synchronized, allowing users to edit, draw and create lines over a 3D image, while also navigating through 3D space.

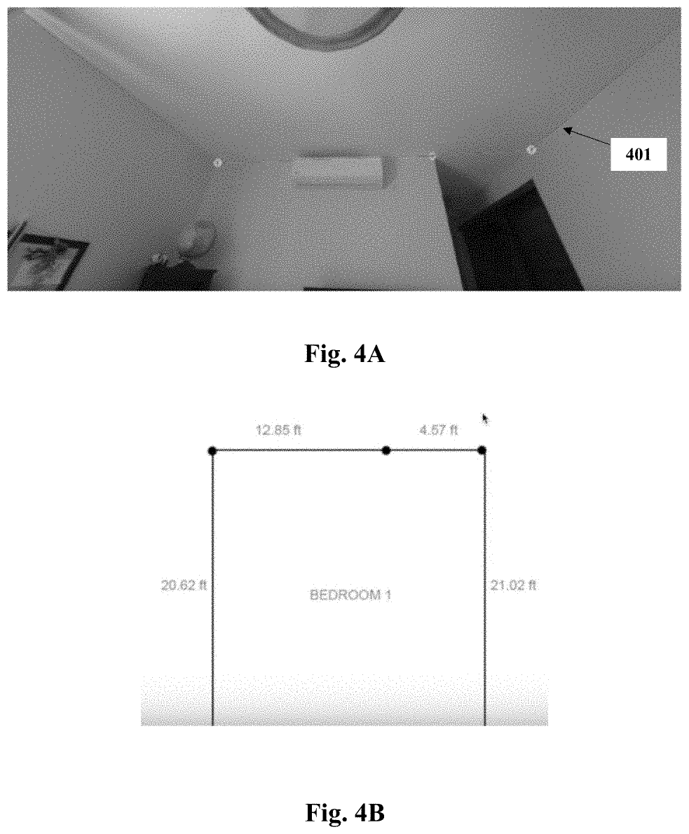

As seen in FIGS. 4A and 4B, the present invention further comprises a computation module 106 that allows for real-time computation of distances between guiding lines (boundary markers) 401 drawn by the user in a 3D space. It also translates, maps, unwraps image data based on the focal length of the 3D camera, adjusting the segments, sections and even radius of the 3D sphere as necessary, in real time. In the case of a 360 degree photo camera, which outputs a 2D image, the computation module maps lines drawn in 3D space into lines over a 2D surface accounting for variables such as camera angle, skew, focal length and other parameters, if necessary. In the case of a 3D camera which contains depth information, this information is computed using distance formula (and/or variations of) in 3D space.

The present invention further comprises a persistent storage module 107, such as a database, where all data including images, user data, user-drawn points, lines, guides, floor plans and any other information relating to the platform are stored. This storage may be integrated to the system, such as an internal hard disk drive, or removable media such as SD cards or flash drives.

The present invention also comprises a floor plan processor module 108. The purpose of said floor plan processor module is to compute floor plans from the boundary markers drawn by the user, in real time. A final floor plan document 109 is generated by a document processor which incorporates the floor plan into an appropriate document format, such as PDF, for final consumption by the end user.

The method object of the present invention may be carried out in the following steps. The first step is loading the interior of the building's 3D photograph. In this step, the user uploads a photograph or video of the interior of the building using a 3D camera. The photograph may also be uploaded from an external source. There are no limits to what type of 3D camera is used as long as the output is a 3D photograph taken with a certain focal length. The only required parameter is to know the focal length of the camera itself. The 3D image is then “unwrapped” into a regular 360-degree panorama (FIG. 2) which the user can freely move in the software interface. The “camera” from which the user can see, is placed directly into the center of the sphere with the image so that it gives the user an illusion that they are looking into a normal cubical room. This is possible because the actual room captured is cubical, which is converted into a sphere by the 3D camera. The sphere's radius is determined by the focal length of the camera and the lens profile used.

When a video source is used, the relevant frames are selected by the processor based on certain parameters (for example, blur level) to be loaded into the application. One of the most important roles of the media processor is to extract the EXIF metadata from images and similar metadata (EXIF, QuickTime, XMP) from videos which are used to calibrate the 3D image mapping inside the virtual 3D environment of the viewer to improve accuracy. For example, EXIF metadata can contain camera make/model details as well as the lens details (such as focal length) which can be used to tune the 3D viewer application for higher accuracy and realism.

The next step is receiving user input for specifying the boundaries. In this step, once the image has been loaded into the interface, the user is now able to mark connecting points onto the image directly which will mark the guides of the floor plan. As previously mentioned, these marking may be achieved by using a touchscreen or conventional methods, such as mouse and keyboard. The software allows the user to draw as many points as necessary so that they can be connected later to form lines. Boundary markers 107 are the building blocks of the floor plans. They help in computation, measurement and visual representation of the floor plans and are used to translate 3D information to 2D floor plans within the floor plan processor module 108. When a user draws a line over the image, he is drawing over the actual surface of the sphere itself. While this is excellent for computation of the accurate distance between two points within this sphere, the shape thus formed doesn't reflect the actual shape in a floor plan (rectangle, for example) since it doesn't account for the curvature of the sphere. To circumvent this, a separate processor is implemented to compute the floor plan itself. The processor's job is to get accurate measurements from the sphere and translate them over a planar surface to recover back the original shape of the plan.

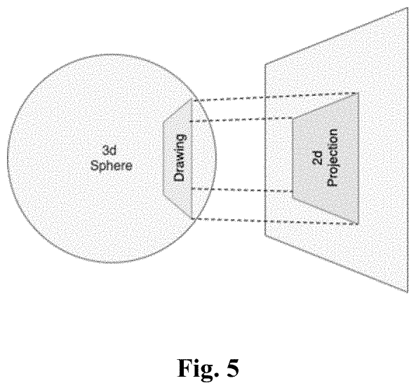

The final step is the computation of the floor plan. Once the guide lines have been input by the user, the software is now able to compute in real time the estimated area floor plans and the outline of the floor plan itself. This is achieved by projecting the drawn lines from the 3D plane onto a 2D plane surface, accounting for skew due to the camera's focal length, orientation and angle, resulting in a mathematical projection as shown in FIG. 5. This floor plan may be exported to a digital file by the floor plan processor module 108.

In a further embodiment of the present invention, a software reporting module and a database are stored on one or more remote computers and accessed by clients via a wide area network. Said database contains measurement information from the captured 3D image of a room. A client may submit identifying information such as name, address, or other, and a request for a report with information from the building related to the provided information. The report contains all the measurement information related to the captured room, such as distance between walls, height, location of exits, etc. Reports may be transmitted electronically, such as via a network (e.g., as an email, Web page, etc.) in a PDF file or any similar digital format, or by some shipping mechanism, such as the postal service, a courier service, etc. The report may be transmitted to various destinations, such as directly to a customer or computing system associated with that customer, a data repository, and/or a quality assurance queue for inspection and/or improvement by a human operator.

The generated report may include one or more annotated views of the captured 3D image or the generated 2D floor plan. In some embodiments, the annotations include numerical values indicating the distance between walls, height, exit locations, or other information. The report may be an electronic file that includes images of the building and/or other rooms, as well as line drawings of one or more views of the 2D floor plan. Preparing the report may include annotating the report with labels that are sized and oriented in a manner that preserves and/or enhances readability of the report. For example, labels on a particular line drawing may be sized based at least in part on the size of the feature (e.g., wall) that they are associated with, such that smaller features are annotated with smaller labels so as to preserve readability of the line drawing by preventing or reducing the occurrence of labels that overlap with other portions (e.g., lines, labels, etc.) of the line drawing.

The present invention may also comprise artificial intelligence and machine learning to completely remove the need for manual user input such as drawing guides for the software to compute.

Although certain exemplary embodiments and methods have been described in some detail, for clarity of understanding and by way of example, it will be apparent from the foregoing disclosure to those skilled in the art that variations, modifications, changes, and adaptations of such embodiments and methods may be made without departing from the true spirit and scope of the claims. Therefore, the above description should not be taken as limiting the scope of the invention which is defined by the appended claims

The invention is not limited to the precise configuration described above. While the invention has been described as having a preferred design, it is understood that many changes, modifications, variations and other uses and applications of the subject invention will, however, become apparent to those skilled in the art without materially departing from the novel teachings and advantages of this invention after considering this specification together with the accompanying drawings. Accordingly, all such changes, modifications, variations and other uses and applications which do not depart from the spirit and scope of the invention are deemed to be covered by this invention as defined in the following claims and their legal equivalents. In the claims, means-plus-function clauses, if any, are intended to cover the structures described herein as performing the recited function and not only structural equivalents but also equivalent structures.

All the patents, patent applications, and publications recited herein, and in the Declaration attached hereto, if any, are hereby incorporated by reference as if set forth in their entirety herein. All, or substantially all, the components disclosed in such patents may be used in the embodiments of the present invention, as well as equivalents thereof. The details in the patents, patent applications, and publications incorporated by reference herein may be considered to be incorporable at applicant's option, into the claims during prosecution as further limitations in the claims to patently distinguish any amended claims from any applied prior art.

1. A system for generating 2D floor plans, comprising:
a computer processor;
a storage module;
a media source;
computer program instructions stored in said storage module to be executed by said computer processor, comprising:
computer program instructions for generating a 3D sphere using a 3D engine software;
computer program instructions for editing an image obtained using said media source using a software image processor;
computer program instructions for showing an updated version of said image after being edited using an interface controller;
computer program instructions for computing a plurality of distances from said image obtained using said media source using a computation module;
computer program instructions for generating a floor plan based on said plurality of distances.

2. The system of claim 1, wherein said media source is a 3D camera.

3. The system of claim 1, wherein said media source is a video camera.

4. The system of claim 1, wherein said 3D engine software is Javascript-based.

5. The system of claim 1, wherein editing an image comprises one of cropping, constraining or creating lines over said image.

6. The system of claim 1, wherein showing an updated version of said image after being edited is done in real-time.

7. The system of claim 1, further comprising a database stored in said storage module.

8. A method for generating 2D floor plans from a 3D picture, comprising the steps of:
generating a 3D sphere;
capturing a 3D image using a media source;
placing said 3D image over said 3D sphere;
drawing a plurality of markers on said 3D image that represent a plurality of boundaries in said 3D image;
computing a plurality of distances between said plurality of markers;
generating a floor plan based on said plurality of distances.

9. The method of claim 6, wherein said media source is a 3D camera.

10. The method of claim 6, wherein said media source is a video camera.

11. The method of claim 6, wherein generating a 3D sphere is done using a 3D engine software.

12. The method of claim 6, wherein generating a 3D sphere is done using a Javascript-based 3D engine software.

13. The method of claim 6, further comprising the step of storing information about said 3D image in a database.
